(19) United States
(12) Patent Application Publication
(10) Pub. No.: US 2020/0147655 A1
(43) Pub. Date: May 14, 2020

(54) SUBSTRATE PROCESSING APPARATUS

(71) Applicant: TOSHIBA MEMORY CORPORATION, Tokyo (JP)

(72) Inventor: Kosuke TAKAI, Yokohama Kanagawa (JP)

(21) Appl. No.: 16/557,769

(22) Filed: Aug. 30, 2019

(30) Foreign Application Priority Data
Nov. 12, 2018 (JP) 2018-212198

(51) Int. Cl. B08B 3/04

(52) U.S. Cl. CPC B08B 3/04

(57) ABSTRACT

A substrate processing apparatus of an embodiment includes a nozzle plate and a support configured to support a substrate at a predetermined distance from the nozzle plate with a first surface of the substrate facing the nozzle plate. A processing liquid supply unit is configured to supply a processing liquid to a second surface of the substrate that is opposite to the first surface. A first supply unit is configured to supply a first fluid from a first supply port in the nozzle plate. A second supply unit is configured to supply a second fluid from a second supply port closer to a outer edge of the nozzle plate than the first supply port.

### CROSS-REFERENCE TO RELATED APPLICATION

This application is based upon and claims the benefit of priority from Japanese Patent Application No. 2018-212198, filed on Nov. 12, 2018, the entire contents of which are incorporated herein by reference.

### FIELD

Embodiments described herein relate generally to a substrate processing apparatus.

### BACKGROUND

In the related art, a freeze cleaning technique is known in which foreign substances are removed from the frontside surface a substrate by bringing a cooling medium into contact with a backside surface to freeze a liquid film on the front surface and then removing the frozen layer.

However, in the freeze cleaning technique of the related art, it is not possible to simultaneously clean the backside surface of the substrate with a chemical liquid while cleaning the frontside surface of the substrate. Furthermore, a cooling medium supplied to the backside surface of the substrate will be brought into contact with cleaning liquid and air such that frozen matter can form at the peripheral edge portion and/or the backside surface of the substrate and the substrate can thus be contaminated.

### DESCRIPTION OF THE DRAWINGS

FIG. 1 is a view schematically illustrating a substrate processing apparatus according to a first embodiment.

FIG. 2 is a top view illustrating a nozzle.

FIG. 3 is a flow chart illustrating a substrate processing method according to the first embodiment.

FIG. 4 is a view schematically illustrating a substrate processing apparatus according to a second embodiment.

FIG. 5 is a top view illustrating a nozzle.

FIG. 6 is a view schematically illustrating a substrate processing apparatus according to a third embodiment.

FIG. 7 is a top view illustrating a support with a substrate placed thereon.

FIGS. 8A and 8B are cross-sectional views schematically illustrating other configurations of a support according to a third embodiment.

FIG. 9 is a cross-sectional view schematically illustrating yet another configuration of a support according to a third embodiment.

FIG. 10 is a view schematically illustrating a substrate processing apparatus according to a fourth embodiment.

FIG. 11 is a top view illustrating a nozzle.

FIG. 12 is a view schematically illustrating a configuration of a substrate processing apparatus according to a fifth embodiment.

FIG. 13 is a view schematically illustrating another configuration of a substrate processing apparatus according to the fifth embodiment.

### DETAILED DESCRIPTION

In general, according to one embodiment, a substrate processing apparatus includes a nozzle plate, a support configured to support a substrate a predetermined distance from the nozzle plate with a first surface of the substrate facing the nozzle plate, a processing liquid supply unit configured to supply a processing liquid to a second surface of the substrate opposite to the first surface, a first supply unit configured to supply a first fluid from a first supply port in the nozzle plate, and a second supply unit configured to supply a second fluid from a second supply port closer to a outer edge of the nozzle plate than the first supply port.

Hereinafter, a substrate processing apparatus according to various example embodiments will be described in detail with reference to the drawings. The present disclosure is not limited to these embodiments.

### First Embodiment

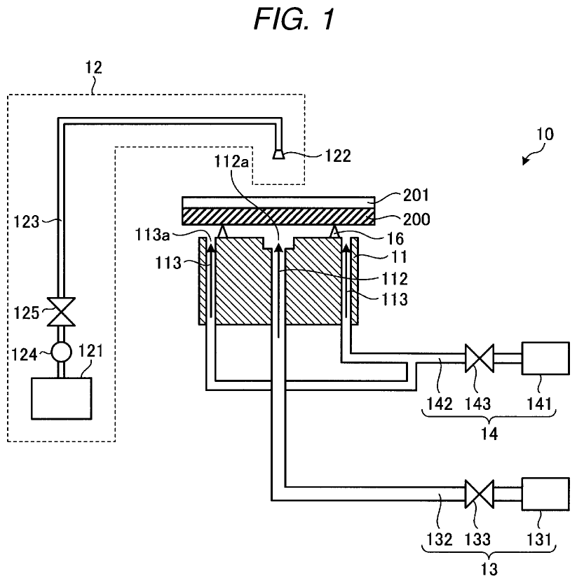

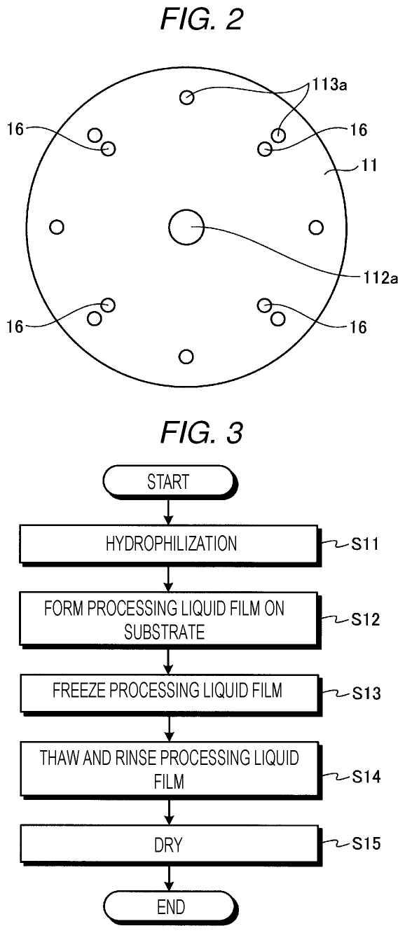

FIG. 1 is a view schematically illustrating a configuration of a substrate processing apparatus according to a first embodiment. FIG. 2 is a top view illustrating a configuration of a nozzle. A substrate processing apparatus 10 according to the first embodiment includes a nozzle plate 11, a processing liquid supply unit 12, a cooling medium supply unit 13, and a heating medium supply unit 14.

The nozzle plate 11 includes openings/ports for spraying a cooling fluid (e.g., a chilled gas, liquid, or mixture) and/or a heating fluid (e.g., a gas, liquid, or mixture that is warmer than the cooling fluid) on the lower surface of a substrate 200 being subjected to freeze cleaning. A support 16 is provided on the nozzle plate 11 to support the substrate 200 at a position higher than an upper surface of the nozzle plate 11. The support 16 supports the substrate 200 at a predetermined distance from the upper surface of the nozzle plate 11 so the cooling medium can be brought into contact with the lower surface of the substrate 200. The substrate 200 is, for example, a semiconductor substrate such as a semiconductor wafer, a glass substrate, a template used in an imprint processing, a photomask used in an exposure processing, a photomask blank before pattern formation, or an extreme ultraviolet (EUV) mask blank. In this context, template includes a replica template used for forming a pattern on a semiconductor substrate, and a master template used for forming a pattern on a replica template. The upper surface of the nozzle plate 11 is substantially horizontal. When the substrate 200 is supported on the support 16, the surface facing away from nozzle plate 11 is referred to as “an upper surface,” and the surface facing the nozzle plate 11 is referred to as “a lower surface.”

A through hole 112 is provided in the vicinity of the center of the nozzle plate 11 in the horizontal plane. The through hole 112 penetrates therethrough in the vertical direction. The portion where the through hole 112 intersects with the upper surface of the nozzle plate 11 is a supply port 112a for the cooling medium. In this example, a diameter of the supply port 112a is larger than that of the through hole 112.

A plurality of through holes 113 are provided in the vicinity of the peripheral edge portion of the nozzle plate 11 in the horizontal plane and penetrate therethrough in the vertical direction. Here, eight through holes 113 are provided equidistantly on a circumference at a predetermined radial distance from the center of the nozzle plate 11. Portions where the through holes 113 intersect with the upper surface of the nozzle plate 11 are supply ports 113a for the heating medium.

The nozzle plate 11 may be configured to be rotatable about an axis perpendicular to the substrate placing surface that passes through the center of the substrate placing surface. In this case, a stopper that prevents movement of the substrate 200 in the horizontal direction due to the rotation of the nozzle plate 11 is provided on the support 16.

The processing liquid supply unit 12 supplies a processing liquid used in the freeze cleaning. The processing liquid supply unit 12 includes a processing liquid storage 121 that stores the processing liquid, a nozzle 122 that dispenses the processing liquid onto the upper surface of the substrate 200, a piping 123 that connects between the nozzle 122 and the processing liquid storage 121, a pump 124 that sends the processing liquid from the processing liquid storage 121 to the nozzle 122 via the piping 123, and a valve 125 that performs switching of the supply of the processing liquid from the processing liquid storage 121 to the nozzle 122. The processing liquid is, for example, pure water, deionized water, or ozone (ozonated) water. When the processing liquid is dispensed onto the substrate 200 from the processing liquid supply unit 12, a processing liquid film 201 is formed on the substrate 200.

At the time of the freeze cleaning, the cooling medium supply unit 13 supplies a cooling medium that cools the substrate 200 to a temperature equal to or lower than the freezing point of the processing liquid. The cooling medium supply unit 13 includes a cooling medium storage 131 that stores the cooling medium, a piping 132 that connects the cooling medium storage 131 to the through hole 112 of the nozzle plate 11, and a valve 133 that performs switching of the supply of the cooling medium. A gas such as nitrogen gas cooled to a temperature lower than the freezing point of the processing liquid, or a liquid such as liquid nitrogen or liquid freon may be used as the cooling medium.

At the time of the freeze cleaning, the heating medium supply unit 14 supplies the heating medium to heat the peripheral edge portion of the lower surface of the substrate 200 to a temperature higher than 0° C. The heating medium supply unit 14 includes a heating medium storage 141 that stores the heating medium, a piping 142 that connects the heating medium storage 141 to the through hole 113 of the nozzle plate 11, and a valve 143 that performs switching of the supply of the heating medium. A gas such as nitrogen gas heated to a temperature higher than the dew point of the air around the nozzle plate 11 may be used as the heating medium. As the heating medium, for example, nitrogen gas at room temperature (e.g., 20° C.) may be used. The term “heating” used herein refers to returning the temperature of the substrate 200 and the processing liquid film 201 to approximately room temperature from a cooled state.

At the time of the freeze cleaning processing, the cooling medium is supplied from the supply port 112a of the nozzle plate 11, and the heating medium is supplied from the supply port 113a. The cooling medium supplied from the supply port 112a flows into a space between the upper surface of the nozzle plate 11 and the lower surface of the substrate 200 from the center of the nozzle plate 11 toward the peripheral edge. Then, the cooling medium is mixed with the heating medium supplied from the supply ports 113a provided in the vicinity of the peripheral edge. The temperature and the flow rate of the cooling medium and the temperature and the flow rate of the heating medium are adjusted such that the temperature of the mixture of the cooling medium and the heating medium discharged from the horizontal edge of the nozzle plate 11 is higher than the freezing point of the processing liquid and the dew point of the air around the nozzle plate 11. As a result, it is possible to prevent formation of frost that would be generated when moisture contained in the air around the nozzle plate 11 is condensed at the peripheral edge of the nozzle plate 11 and the substrate 200, or a frozen layer of the processing liquid hanging down from the side surface and/or the lower surface of the substrate 200.

Next, the processing method for such a substrate processing apparatus is described. FIG. 3 is a flow chart illustrating a procedure of the substrate processing method according to the first embodiment. First, the surface of the substrate 200 to be processed is hydrophilized before the freeze cleaning (step S11). The hydrophilization is performed by, for example, irradiating the surface of the substrate 200 with ultraviolet (UV). As a result, the surface of the substrate 200 is easily wetted with the processing liquid used in the freeze cleaning. Then, the now hydrophilized substrate 200 is supported by the support 16.

Next, the processing liquid is supplied from the nozzle 122 onto the substrate 200 via the piping 123 by the pump 124, and the processing liquid film 201 is formed on the upper surface of the substrate 200 (step S12). At this time, if the nozzle plate 11 is rotated about the axis perpendicular to the substrate placing portion, it is possible to form a processing liquid film 201 which is substantially uniformly spreads over the entire surface of the substrate 200.

Thereafter, a cooling medium is supplied from the cooling medium supply unit 13 to the supply port 112a of the nozzle plate 11 via the piping 132. Further, a heating medium is supplied to the peripheral edge portion of the space between the nozzle plate 11 and the lower surface of the substrate 200 from the heating medium supply unit 14 via the supply port 113a of the nozzle plate 11. The cooling medium ejected from the supply port 113a at the center of the nozzle plate 11 flows into the gap between the lower surface of the substrate 200 and the upper surface of the nozzle plate 11 toward the outer peripheral edge. At this time, since the lower surface of the substrate 200 is being brought into contact with the cooling medium, the substrate 200 is cooled from the lower surface side. Then, the temperature of the upper surface side of the substrate 200 becomes equal to or lower than the freezing point of the processing liquid, and, if necessary, further cooling may cause the processing liquid film 201 to be frozen after experiencing a supercooled state (step S13). The processing liquid film 201 freezes from the portion in contact with the substrate 200 upwards.

Further, the cooling medium that flows into the space between the lower surface of the substrate 200 and the upper surface of the nozzle plate 11 toward the peripheral edge portion is mixed with the heating medium supplied from the supply port 113a. The flow rates and the temperatures of the cooling medium and the heating medium can be adjusted such that the temperature of the fluid discharged from the gap between the nozzle plate 11 and the lower surface of the substrate 200 becomes sufficiently higher than the dew point of the air around the nozzle plate 11. Therefore, the moisture contained in the air around the nozzle plate 11 is not condensed at the peripheral edge portion of the nozzle plate 11 or the substrate 200. Furthermore, frozen processing liquid will not form on the side surface or lower surface of the substrate 200.

After the processing liquid film 201 is frozen, the valve 133 is closed to stop the supply of the cooling medium from the cooling medium supply unit 13 and the supply of the heating medium from the heating medium supply unit 14 can be stopped. Additional processing liquid from the processing liquid supply unit 12 can be supplied to the upper surface of the substrate 200 via the nozzle 122, and a rinse processing performed (step S14). As a result, the frozen processing liquid film 201 is thawed, and the processing liquid film 201 that now contains foreign substances from the upper surface of the substrate 200 is removed. The thawing processing and the rinse processing for the processing liquid film 201 may be performed after the processing liquid film 201 has frozen over its entire film thickness, or may be performed some portion of the processing liquid film 201, for example, a portion having a predetermined layer thickness of about 100 nm has frozen on the upper surface of with the substrate 200. Thereafter, the substrate 200 is dried (step S15), and the freeze cleaning processing of the substrate 200 is completed.

If the foreign substances attached on the upper surface of the substrate 200 are not sufficiently removed by performing steps S11 to S15 a single time, then steps S12 to S14 may be repeatedly performed a plurality of times.

In FIG. 1, the case where the area of the nozzle plate 11 is smaller than the area of the substrate 200 is illustrated, but in other examples the area of the nozzle plate 11 may be substantially the same as the area of the substrate 200.

In the first embodiment, during the freeze cleaning processing, the cooling medium is supplied from near the center of the nozzle plate 11 on which the substrate 200 is placed, and the heating medium is supplied from near the outer edge of the nozzle plate 11. During the freeze cleaning processing, the temperature of the mixed medium (formed by mixing the cooling medium and the heating medium) discharged from the gap between the lower surface of the substrate 200 and the upper surface of the nozzle plate 11 is set to be sufficiently higher than the dew point of the air around the nozzle plate 11 and the freezing point of the processing liquid. Therefore, the moisture contained in the air around the nozzle plate 11 is not condensed at the peripheral edge portion of the nozzle plate 11 and the peripheral edge portion of the lower surface of the substrate 200, and further, the processing liquid 200 is not frozen at the side surface and/or lower surface of the substrate 200. As described above, since it is possible to prevent the formation of a condensed substance at the peripheral edge portion of the nozzle plate 11 and on lower surface of the substrate 200, the contamination of the lower surface of the substrate 200 can be prevented.

### Second Embodiment

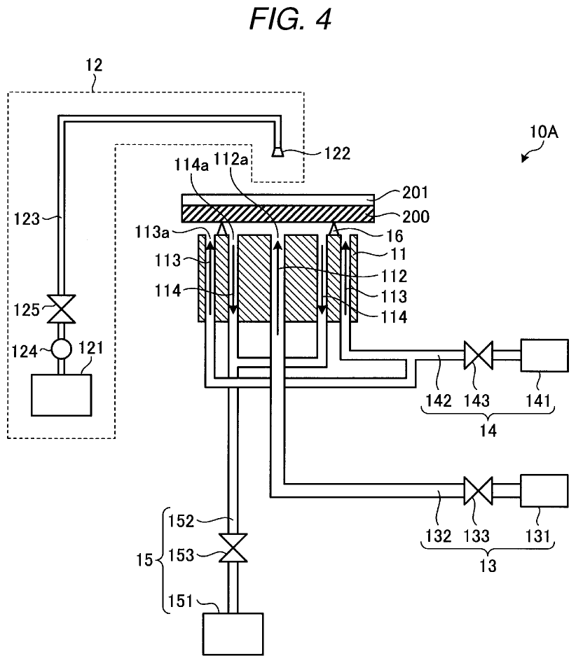

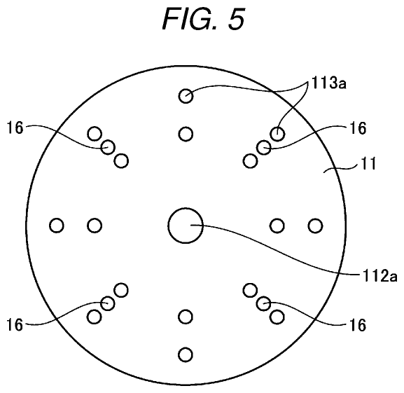

FIG. 4 is a view schematically illustrating a configuration of a substrate processing apparatus according to a second embodiment. FIG. 5 is a top view illustrating a configuration of a nozzle. A substrate processing apparatus 10A according to the second embodiment includes a suction unit 15, in addition to the aspects of the substrate processing apparatus 10 according to the first embodiment. Furthermore, through holes 114 are provided in a region between the center of the nozzle plate 11 and the region in which the through holes 113 are provided. Portions at which the through holes 114 intersect with the upper surface of the nozzle plate 11 serve as suction ports 114a.

The suction unit 15 sucks the cooling medium and the heating medium from the space between the upper surface of the nozzle plate 11 and the lower surface of the substrate 200 in the freeze cleaning. The suction unit 15 includes a suction unit 151 that intakes cooling medium and heating medium, a piping 152 that connects the suction unit 151 to the through holes 114 of the nozzle plate 11, and a valve 153 that performs switching of the suction of the cooling medium and the heating medium. For example, a vacuum pump may be used as the suction unit 151. The same components as those in the first embodiment are denoted by the same reference numerals, and redundant explanations are omitted.

Operation of the substrate processing apparatus 10A will be described. The cooling medium is supplied from the supply ports 112a, the heating medium is supplied from the supply ports 113a, and the cooling medium and the heating medium are suctioned into the suction ports 114a. Both cooling medium and the heating medium can be suction into the suction ports 114a. However, since the suction ports 114a are provided on the passage route for the cooling medium from the center to the edge, mainly the cooling medium will be sucked into the suction ports 114a. Here, the temperatures and the flow rates of the cooling medium and/or the heating medium along with the suction force can be adjusted such that the temperature of the fluid discharged from the gap between the upper surface of the nozzle plate 11 and the lower surface of the substrate 200 is sufficiently higher than the dew point of the air around the nozzle plate 11. As a result, it is possible to prevent formation of frost at the peripheral edge portions of the nozzle plate 11 and the substrate 200, or a frozen layer of the processing liquid hanging down from the side surface and/or the lower surface of the substrate 200. Since the overall aspects of the freeze cleaning processing method with the substrate processing apparatus 10A are the same as the first embodiment, the descriptions thereof are omitted.

In the second embodiment, during the freeze cleaning processing, the cooling medium is supplied from near the center of the nozzle plate 11 on which the substrate 200 has been placed, and the heating medium is supplied from near the peripheral edge portion of the nozzle plate 11. The cooling medium is mainly sucked into the suction ports 114a that are provided in the region between the supply port 112a for the cooling medium and the supply ports 113a for the heating medium. At this time, the suction amount, the temperature and the flow rate of the cooling medium, and the temperature and the flow rate of the heating medium are adjusted such that the temperature of the mixed medium discharged from the space between the lower surface of the substrate 200 and the upper surface of the nozzle plate 11 becomes sufficiently higher than the dew point of the air around the nozzle plate 11 and the freezing point of the processing liquid. As a result, the moisture contained in the air around the nozzle plate 11 is not condensed at the peripheral edge portion of the nozzle plate 11 and the peripheral edge portion of the lower surface of the substrate 200, and a frozen layer of the processing liquid hanging down from the side surface and/or the lower surface of the substrate 200 is not formed.

As described above, since it is possible to prevent the formation of a condensed/frozen substance at the peripheral edge portion of the nozzle plate 11 and the lower surface of the substrate 200 and to the lower surface, the contamination of the lower surface of the substrate 200 can be prevented.

### Third Embodiment

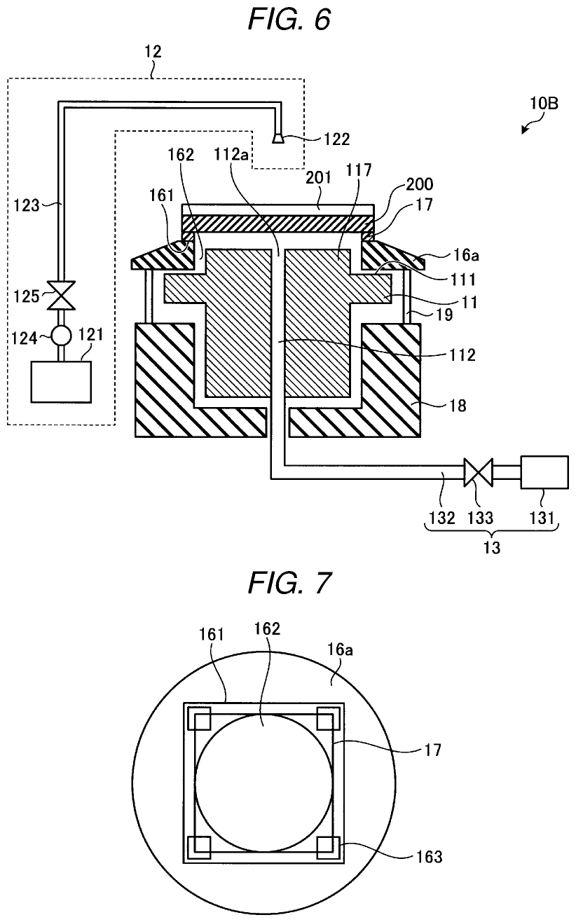

FIG. 6 is a view schematically illustrating a configuration of a substrate processing apparatus according to a third embodiment. FIG. 7 is a top view illustrating a configuration of a support in a state in which a substrate has been placed thereon. Hereinafter, descriptions on the same parts as those of the first embodiment will be omitted, and only different parts will be described. In a substrate processing apparatus 10B according to the third embodiment, the configurations of the nozzle and the substrate support are different from the first embodiment. The nozzle plate 11 includes a convex portion 117 that is protruded from an upper surface 111 in the vicinity of the center. The area of the convex portion 117 in the horizontal direction is less than the area of the substrate 200. The through hole 112 is provided near the center of the nozzle plate 11. The portion where the through hole 112 intersects with the upper surface of the nozzle plate 11 is the supply port 112a for the cooling medium.

The support 16a has an annular shape having an opening 162 in the center and surrounding the periphery of the convex portion 117 of the nozzle plate 11. The support 16a is made of, for example, a ceramic material or a resin material, such as polytetrafluoroethylene. The size of the opening 162 in the horizontal surface is larger than the area of the convex portion 117 of the nozzle plate 11, but smaller than the area of the substrate 200. A flat portion 161 is provided in the region of the inner peripheral side of the upper surface of the support 16a on which the substrate 200 is placed. The flat portion 161 including the opening 162 therein has a rectangular shape. A seal member 17 is provided on the flat portion 161 along the peripheral edge portion of the rectangular shape. The seal member 17 is made of a resin having elasticity, and for example, is made of a rubber such as silicone rubber.

A stopper 163 is provided at the four corner portions of the flat portion 161 to prevent the substrate 200 from being shifted in the horizontal direction. As a result, when the substrate 200 is placed on the seal member 17, gas cannot pass between the upper surface and the lower surface of the support 16a on which the substrate 200 is placed. The seal member 17 is desirably provided continuously on the inner peripheral side of the support 16a, but a portion thereof may be missing. As depicted in FIG. 6, the support 16a has a tapered shape in which the upper surface of the support 16a is angled from the flat portion 161 toward the outer periphery side.

The support 16a is not in contact with the upper surface of the nozzle plate 11. Further, the position of the upper surface of the inner peripheral side of the support 16a is higher than the position of the upper surface of the convex portion 117 of the nozzle plate 11. As a result, a continuous space is provided between the upper surface 111 of the peripheral edge portion of the nozzle plate 11 and the lower surface of the support 16a, and between the upper surface of the convex portion 117 of the nozzle plate 11 and the lower surface of the substrate 200 placed on the support 16a. The support 16a is disposed on a pedestal portion 18 provided below the nozzle plate 11 via the connection portion 19. The pedestal portion 18 is configured to be rotatable in the horizontal plane by, for example, a motor.

In the substrate processing apparatus 10B, the flow rate of the cooling medium from the supply port 112a is set such that the cooling medium flows from the center of the nozzle plate 11 toward the peripheral edge portion. The cooling medium flows from the center of the convex portion 117 toward the peripheral edge of the nozzle plate 11. It is possible to prevent the air outside the nozzle plate 11 from entering the space between the nozzle plate 11 and the support 16a, during the cooling of the lower surface of the substrate 200. Further, with the support 16a on which the substrate 200 is placed, gas cannot easily pass between the upper surface and the lower surface of the substrate 200 through the opening 162. Therefore, the ambient air does not enter into the space between the substrate 200 and the nozzle plate 11. As a result, it is possible to prevent the formation of frost at the peripheral edge portion of the lower surface of the substrate 200.

Further, it is possible to prevent the processing liquid wrapping around from the side surface to the lower surface of the substrate 200. That is, it is possible to prevent the contamination of the lower surface of the substrate from the processing liquid at the side surface of the substrate 200.

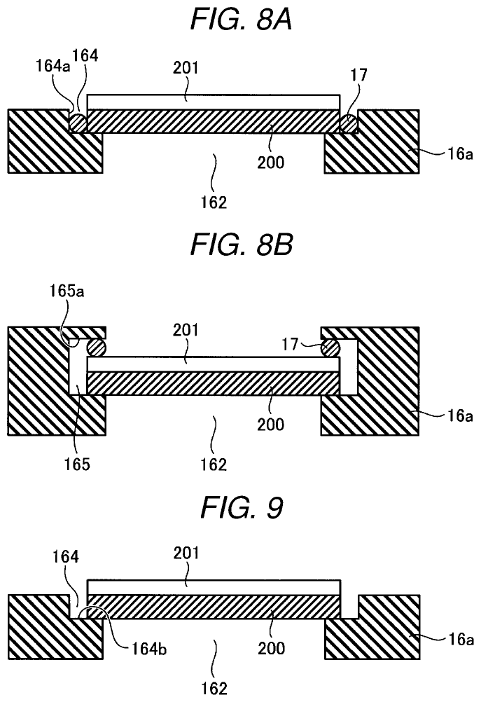

In FIG. 6, the case where a seal member 17 is provided on the flat portion of the inner peripheral side of the support is illustrated, but embodiments are not limited thereto. FIGS. 8A, 8B, and 9 are cross-sectional views schematically illustrating other possible configurations of a support according to a third embodiment. As illustrated in FIG. 8A, a concave portion 164 having a rectangular shape including an opening 162 may be provided on the inner peripheral side of the annular support 16a, and the substrate 200 may be placed on the concave portion 164. At this time, the seal member 17 may be provided along a side surface 164a of the concave portion 164 to block the flow of gas between the upper surface and the lower surface of the support 16a on which the substrate 200 is placed.

Further, as illustrated in FIG. 8B, a concave portion 165 having a rectangular shape including the opening 162 may be provided on the inner peripheral side of the annular support 16a, and the substrate 200 may be placed on the concave portion 165. At this time, the seal member 17 may be provided along an upper surface 165a of the concave portion 165 to block the flow of gas between the upper surface and the lower surface of the support 16a on which the substrate 200 is placed.

Furthermore, as illustrated in FIG. 9, a surface receiving structure may be adopted in which the substrate 200 is placed on the support 16a without the seal member 17. As illustrated in FIG. 9, similar to FIG. 8A, a concave portion 164 having a rectangular shape including an opening 162 is provided on the inner peripheral side of the annular support 16a, and the substrate 200 is placed on a bottom surface 164b of the concave portion 164. No seal member 17 is utilized in this example.

Since the overall aspects of the freeze cleaning processing method in the substrate processing apparatus 10B is the same as the first embodiment, the descriptions thereof are omitted.

In the third embodiment, the substrate 200 is placed on the support 16a to block the opening 162, and the cooling medium is supplied from the vicinity of the center of the nozzle plate 11 in a state in which the support 16a is disposed at a predetermined distance from the upper surface of the nozzle plate 11. As a result, during the freeze cleaning processing, the cooling medium is discharged from the space between the lower surface of the substrate 200 and the upper surface of the nozzle plate 11. Frost might potentially be formed at the peripheral edge portion of the nozzle plate 11 due to freezing of the moisture contained in the ambient air. However, since the position where the frost would be formed is well separated from the substrate 200, the lower surface of the substrate 200 will not be contaminated by frost.

Further, the ambient air and the processing liquid dispensed on the substrate 200 find it difficult to pass from the upper surface of the support 16a to the lower surface of the substrate. Therefore, the condensed material such as frost formed by water vapor and a side edge frozen layer formed by the processing liquid is prevented from being attached to the lower surface of the substrate 200. As a result, the contamination of the lower surface of the substrate 200 can be prevented.

### Fourth Embodiment

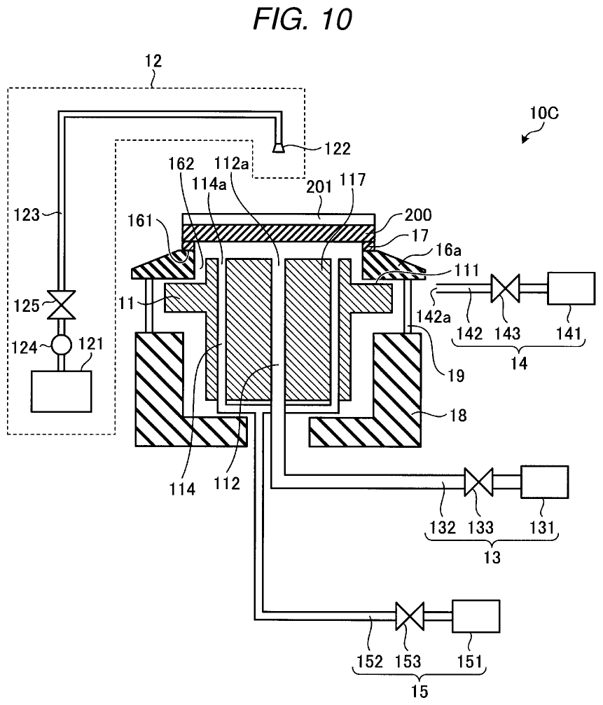

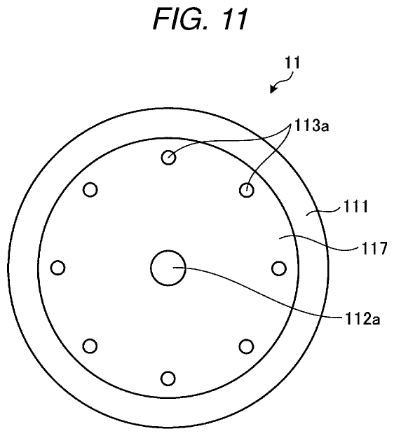

FIG. 10 is a view schematically illustrating a configuration of a substrate processing apparatus according to a fourth embodiment. FIG. 11 is a top view illustrating a configuration of a nozzle. Hereinafter, descriptions on the same parts as those of the first to third embodiments will be omitted, and only different parts will be described. A substrate processing apparatus 10C according to the fourth embodiment is conceptually a combination of the third embodiment and the second embodiment. The substrate processing apparatus 10C includes a heating medium supply unit 14 and a suction unit 15 as in the configuration of FIG. 6.

The through holes 114 are provided in the region of the peripheral edge portion of the convex portion 117 of the nozzle plate 11. The portion where the through holes 114 intersect with the upper surface of the nozzle plate 11 are suction ports 114a.

In this embodiment, the heating medium supply unit 14 is provided such that a discharge port 142a faces the space between the upper surface 111 of the nozzle plate 11 and the lower surface of the support 16a. A plurality of discharge ports 142a may be provided at a plurality of positions around the nozzle plate 11. The heating medium is, for example, nitrogen at room temperature, or air (dry air) which does not contain water vapor. The heating medium supply unit 14 supplies the heating medium such that the cooling medium is not discharged to the outside at a temperature lower than 0° C.

Operation of the substrate processing apparatus 10C will be described. The cooling medium is supplied from the supply port 112a of the nozzle plate 11, the heating medium is supplied from the discharge port 142a, and the cooling medium and the heating medium can be suctioned into the suction port 114a. Both the cooling medium and the heating can be are suctioned into the suction port 114a. However, since the suction port 114a is provided on the flow passage of the cooling medium, it is the cooling medium that is mainly sucked into the suction port 114a.

Since the position of the suction port 114a is between the center of the nozzle plate 11 and the seal member 17, it is possible to reduce the amount of the cooling medium that reaches the seal member 17. The heating medium supplied from the discharge port 142a mixes in the space near the side surface of the convex portion 117 of the nozzle plate 11, and the temperature becomes higher than would be the case of the cooling medium alone. Thus, it is possible to prevent the temperature the seal member 17 from falling too far. Since the overall aspects of the freeze cleaning processing method in the substrate processing apparatus 10C is the same as the first embodiment, the descriptions thereof are omitted.

In FIG. 10, the case where the heating medium supply unit 14 is provided outside the side surface of the nozzle plate 11 is illustrated. However, similarly to that illustrated in FIG. 4, the heating medium supply unit 14 may instead be disposed on the peripheral edge portion of the convex portion 117 of the nozzle plate 11. In this case, the suction port 114a would be provided in the region on the upper surface of the convex portion 117 between the supply port 112a and the supply port of the heating medium.

In the fourth embodiment, during the freeze cleaning processing, the cooling medium is supplied from near the center of the nozzle plate 11 on which the substrate 200 has been placed, and the heating medium is supplied between side surface of the nozzle plate 11 and the support 16a. Further, the cooling medium can be removed by suction ports 114a. Thus, it is possible to reduce the amount of the cooling medium that reaches the seal member 17. Further, by supplying the heating medium, it is possible to prevent the cooling medium from flowing out from the side surface of the nozzle plate 11 at less than 0° C., and also to increase the temperature of the cooling medium in the vicinity of the seal member 17. As a result, it is possible to prolong the function of the seal member 17 while preventing contamination of the back surface of the substrate 200 and the deterioration of the seal member 17.

### Fifth Embodiment

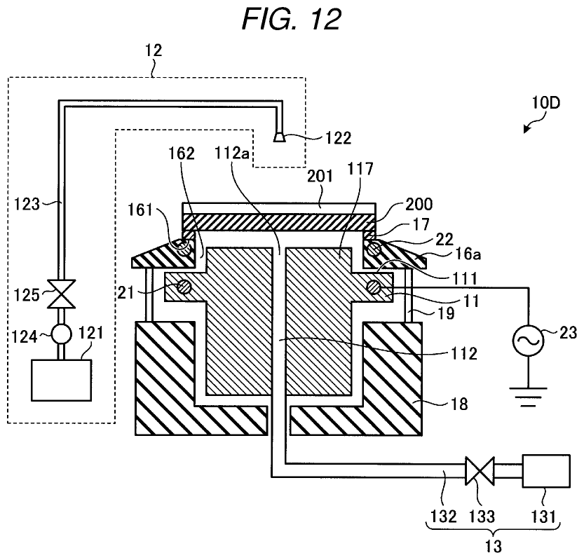

FIG. 12 is a view schematically illustrating a configuration of a substrate processing apparatus according to a fifth embodiment. Hereinafter, descriptions on the same parts as those of the first to fourth embodiments will not be described, and only different parts will be described. An inductive heating mechanism that is configured to heat the seal member 17 in the substrate processing apparatus 10D according to the fifth embodiment. Specifically, a first coil 21 is provided at a position inside the nozzle plate 11 corresponding to the position of the seal member 17 in plan view (see FIG. 7 for plan view shape of seal member 17). The first coil 21 has a rectangular annular shape in plan view like the seal member 17. A high-frequency power supply 23 is connected to the first coil 21. Further, a second coil 22 is provided at a position inside the support 16a corresponding to the position of the seal member 17 in plan view. The second coil 22 also has a rectangular annular shape as the same as the first coil 21 in plan view. The second coil 22 is close to the seal member 17. The first coil 21 and the second coil 22 are provided at substantially the same, overlapping position in plan view.

When the high-frequency power supply 23 is turned ON, a high-frequency current flows through the first coil 21, and an induced current flows through the second coil 22. The second coil 22 is heated by the induced current. The seal member 17 on the support 16a is thus heated by the heating of the second coil 22. Therefore, when the substrate 200 is cooled, the temperature of the seal member 17 does not decrease as much as the substrate 200, and thus, deterioration due to the cooling of the seal member 17 can be prevented. Since the overall aspects of the freeze cleaning processing method in the substrate processing apparatus 10D is the same as the first embodiment, the descriptions thereof are omitted.

In FIG. 12, the case where the second coil 22 is embedded in the support 16a is illustrated, but embodiments are not limited thereto. For example, the seal member 17 itself may be electrically conductive and inductively heated when the high-frequency current flows through the first coil 21.

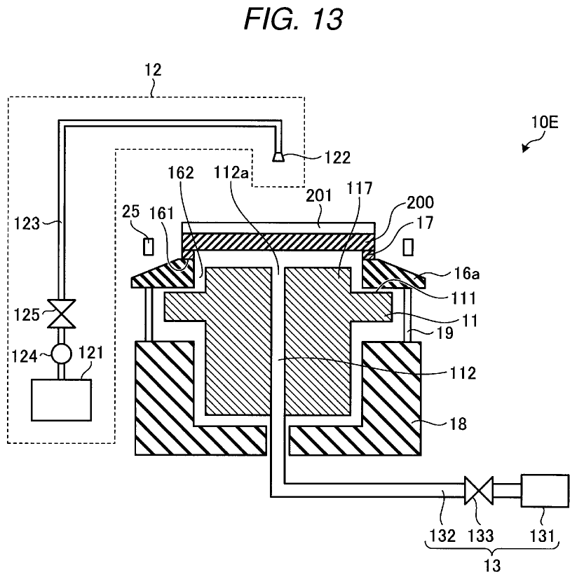

Further, in FIG. 12, the case where the seal member 17 is heated by an inductive heating mechanism is illustrated, but embodiments are not limited thereto. FIG. 13 is a view schematically illustrating another configuration of a substrate processing apparatus according to the fifth embodiment. In a substrate processing apparatus 10E in FIG. 13, an inductive heating mechanism is not provided, but rather a heating mechanism such as a heat lamp is provided. The heating mechanism includes a light source 25. The light source 25 is disposed such that the light from the light source 25 is directed towards the seal member 17. In the example illustrated in FIG. 12, the light source 25 is disposed on the lateral side of the seal member 17. When a power supply is turned ON at the time of the freeze cleaning processing, and the light source 25 preheats the seal member 17.

In the fifth embodiment, a heating unit that heats the seal member 17 is provided. As a result, at the time of the freeze cleaning, it is possible to prolong the function of the seal member 17 as compared to the fourth embodiment.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A substrate processing apparatus, comprising:
a nozzle plate;
a support configured to support a substrate at a predetermined distance from the nozzle plate with a first surface of the substrate facing the nozzle plate;
a processing liquid supply unit configured to supply a processing liquid to a second surface of the substrate opposite to the first surface;
a first supply unit configured to supply a first fluid from a first supply port in the nozzle plate; and
a second supply unit configured to supply a second fluid from a second supply port closer to a outer edge of the nozzle plate than the first supply port.

2. The substrate processing apparatus according to claim 1, further comprising:
a suction unit configured to apply suction to a suction port in the nozzle plate.

3. The substrate processing apparatus according to claim 2, wherein the suction port is in a region of the nozzle plate between the first supply port and the second supply port.

4. The substrate processing apparatus according to claim 1, wherein the support protrudes from an upper surface of the nozzle plate.

5. The substrate processing apparatus according to claim 1, wherein
a central portion of an upper surface of the nozzle plate protrudes beyond an outer peripheral portion of the upper surface of the nozzle plate, and
the support includes an opening that is larger in area than the central portion of the upper surface of the nozzle plate.

6. The substrate processing apparatus according to claim 5, further comprising:
a sealing member on the support to be between the support and the substrate when the substrate is supported on the support.

7. The substrate processing apparatus according to claim 6, further comprising:
a heating unit to heat the sealing member.

8. The substrate processing apparatus according to claim 7, wherein the heating unit includes:
a first coil at in the nozzle plate at a position corresponding to a position of the sealing member,
a high-frequency power supply connected to the first coil, and
a second coil in the support at a position corresponding to the position of the sealing member.

9. The substrate processing apparatus according to claim 7, wherein the heating unit is a heating lamp.

10. A substrate processing apparatus, comprising:
a nozzle plate having an upper surface;
a support configured to support a substrate at a predetermined distance from the nozzle plate with a first surface of the substrate facing the upper surface of the nozzle plate;
a processing liquid supply unit configured to supply a processing liquid to a second surface of the substrate opposite to the first surface;
a first supply unit configured to supply a first fluid from a first supply port in the upper surface of the nozzle plate; and
a suction unit configured to apply suction to a suction port in the upper surface of the nozzle plate.

11. A substrate processing apparatus, comprising:
a nozzle plate having an upper surface;
a support configured to support a substrate at a predetermined distance from the upper surface of the nozzle plate, a first surface of the substrate facing the upper surface of the nozzle plate when supported on the support;
a processing liquid supply unit configured to supply a processing liquid to a second surface of the substrate opposite to the first surface when the substrate is supported on the support; and
a first supply unit configured to supply a first fluid from a first supply port in the nozzle plate to the first surface of the substrate, wherein
a central portion of the upper surface of the nozzle plate protrudes beyond an outer edge of the nozzle plate,
the support includes an opening that is larger in area than the central portion of the upper surface of the nozzle plate, and
an outer peripheral portion of the support forms a gap with an outer peripheral portion of the nozzle plate.

12. The substrate processing apparatus according to claim 11, further comprising:
a sealing member on the support to be between the support and the substrate when the substrate is supported on the support.

13. The substrate processing apparatus according to claim 12, wherein the sealing member comprises elastic resin.

14. The substrate processing apparatus according to claim 13, further comprising:
a heater configured to heat the sealing member.

15. The substrate processing apparatus according to claim 14, wherein the heater includes:
a first coil at in the nozzle plate at a position corresponding to a position of the sealing member,
a high-frequency power supply connected to the first coil, and
a second coil in the support at a position corresponding to the position of the sealing member.

16. The substrate processing apparatus according to claim 14, wherein the heater is a heat lamp.

17. The substrate processing apparatus according to claim 11, further comprising:
a second supply unit configured to supply a second fluid from a second supply port to the upper surface of the nozzle plate.

18. The substrate processing apparatus according to claim 17, wherein the second supply port is in an outer peripheral portion of the central portion of the upper surface of the nozzle plate.

19. The substrate processing apparatus according to claim 17, wherein the second supply port faces a lateral edge of the nozzle plate.

20. The substrate processing apparatus according to claim 11, further comprising:
a suction unit configured to apply suction to a suction port in the upper surface of the nozzle plate.
